(19) United States
(12) Patent Application Publication
(10) Pub. No.: US 2014/0199561 A1
(43) Pub. Date: Jul. 17, 2014

(54) COATED ARTICLE AND METHOD FOR MANUFACTURING SAME

(71) Applicants: SHENZHEN FUTAIHONG PRECISION INDUSTRY CO., LTD., Shenzhen (CN); FIH (HONG KONG) LIMITED, Kowloon (HK)

(72) Inventors: CHUN-JIE ZHANG, Shenzhen (CN); XU LIU, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/866,403

(22) Filed: Apr. 19, 2013

(30) Foreign Application Priority Data
Jan. 15, 2013 (CN) 201310013681.0

(51) Int. Cl. C23C 14/34; B32B 15/04

(52) U.S. Cl. CPC C23C 14/3414; B32B 15/043
USPC 428/627; 204/192.15

(57) ABSTRACT

A coated article includes a stainless steel substrate, a primer layer, a transition layer, and a hard layer formed directly on the stainless steel substrate in that order. The primer layer is a Ti layer. The transition layer is TiₐCr_{b} layer, wherein 1≦a≦2 and 2≦b≦3. The hard layer is a TiₓCr_{y}N_{z} layer, wherein 2≦x≦4, 3≦y≦8 and 10≦z≦16. A method for manufacturing the coated article is also provided.

### BACKGROUND

1. Technical Field

The present disclosure relates to an article coated with a hard layer, and method for manufacturing the article.

2. Description of Related Art

Physical vapor deposition (PVD) can be used to form a hard coating having superior abrasion resistance and chemical resistance. However, the coatings formed by PVD have a low density, thus limiting the further improvement of hardness of the coatings.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary coated article and method for manufacturing the article. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of a coated article.

FIG. 2 is a schematic view of a vacuum sputtering device for manufacturing the coated article in FIG. 1.

### DETAILED DESCRIPTION

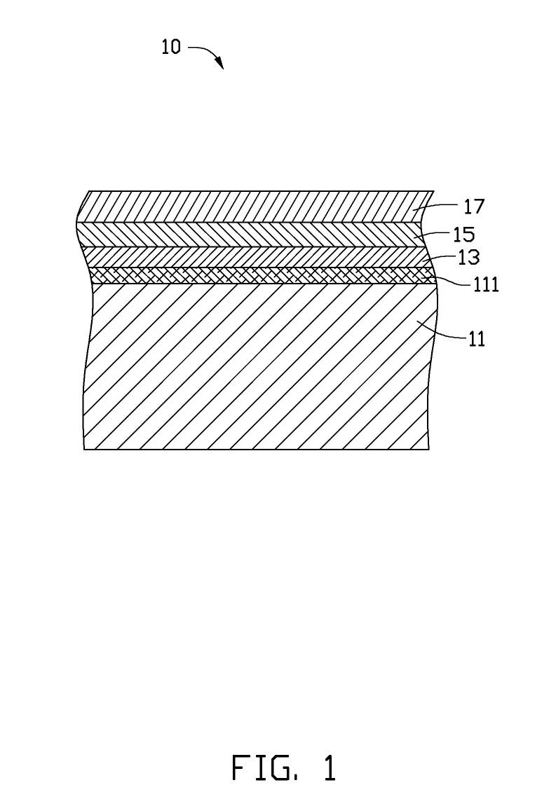

FIG. 1 shows a coated article 10 according to an exemplary embodiment. The coated article 10 includes a stainless steel substrate 11, and the coated article 10 further includes a primer layer 13, a transition layer 15, and a hard layer 17 formed directly on the stainless steel substrate 11 in that order.

The stainless steel substrate 11 has an ion implantation layer 111. The primer layer 13 is formed directly on the ion implantation layer 111. The ion implantation layer 111 substantially includes Fe element and N element, wherein the atomic ratio of the Fe to N is about 1:4 to about 1:7. The thickness of the ion implantation layer 111 is about 0.1 micrometer (μm) to about 0.2 μm.

The primer layer 13 is a Ti layer. The primer layer 13 has a thickness of about 0.3 μm to about 0.5 μm.

The transition layer 15 is formed directly on the primer layer 13. The transition layer 15 is a TiₐCr_{b} layer, wherein 1≦a≦2, 2≦b≦3. The transition layer 15 has a thickness of about 0.5 μm to about 0.8 μm.

The hard layer 17 is formed directly on the transition layer 15. The hard layer 17 is a TiₓCr_{y}N, layer, wherein 2≦x≦4, 3≦y≦8 and 10≦z≦16. The hard layer 17 has a thickness of about 1.2 μm to about 1.5 μm.

A method for manufacturing the coated article 10 may include following steps:

A stainless steel substrate 11 is provided.

Nitrogen ion is implanted into the stainless steel substrate 11 to form the ion implantation layer 111 by ion implantation process.

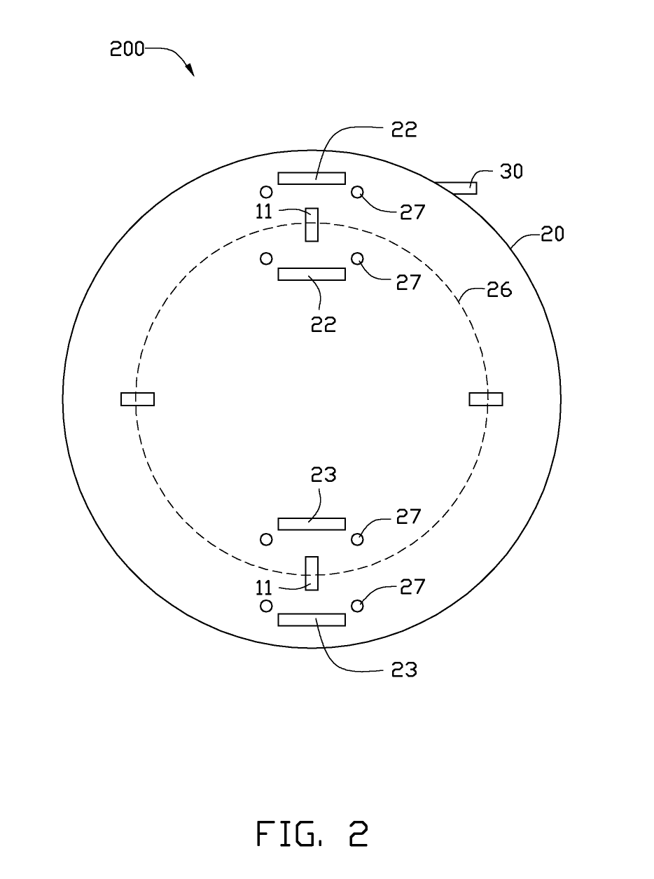

FIG. 2 is an embodiment a vacuum sputtering device 200. The vacuum sputtering device 200 includes a chamber 20, and a vacuum pump 30 connected to the chamber 20. The vacuum pump 30 is used to evacuate the chamber 20. The vacuum sputtering device 200 further includes two Ti targets 22, two Cr targets 23, a rotating bracket 26, and a radio frequency (RF) electrode (not shown) mounted therein, and a plurality of gas inlets 27. The RF electrode is located on the top inner wall of the chamber 20. The rotating bracket 26 rotates the stainless steel substrate 11 in the chamber 20 relative to the Ti targets 22 and the Cr targets 23. The two Ti targets 22 face each other, and are located on opposite two sides of the rotating bracket 26. The two Cr targets 22 face each other, and are located on the opposite two sides of the rotating bracket 26.

The RF electrode is used to ionize ions sputtered from Ti targets 22 and/or Cr targets 23, and gas such as argon gas and nitrogen gas into plasma.

The ion implantation process may be performed under the following conditions. The stainless steel substrate 11 is mounted on the rotating bracket 26 in the chamber 20. The chamber 20 is evacuated to about 2×10⁻¹ Pa to about 8×10⁻¹ Pa. The temperature of the inside of the chamber 20 is heated to about 200 Celsius degree CC) to about 250° C. The electric current of the RF electrode is set about 5 A to about 8 A. A bias voltage of about −1300 volts (V) to about −1500 V may be applied to the stainless steel substrate 11. Argon gas is fed into the chamber 20 at a flux rate of about 100 Standard Cubic Centimeters per Minute (sccm) to about 200 sccm by the gas inlets 24. Nitrogen gas is fed into the chamber 20 at a flux rate about 200 sccm to about 600 sccm by the gas inlets 24. The ion implantation process may take about 20 minutes (min) to about 35 min.

During the ion implantation process, argon gas is ionized by RF electrode to argon plasma, and nitrogen gas is ionized by RF electrode to nitrogen plasma.

The ion implantation layer 111 substantially includes Fe element and N element, wherein Fe element is provided by the stainless steel substrate 11, N element is provided by nitrogen plasma implanted into the stainless steel substrate 11. In the ion implantation layer 111, the atomic ratio of the Fe to N is about 1:4 to about 1:7. The thickness of the ion implanted ion is about 0.1 μm to about 0.2 μm. The ion implantation layer 111 provides an improved hardness to the stainless steel substrate 11.

The primer layer 13 is deposited directly on the ion implantation layer 111. The temperature of the inside of the chamber 20 is set to about 150° C. to about 200° C. The electric current of the RF electrode is set about 5 A to about 8 A. Argon gas is fed into the chamber 20 at a flux rate about 100 sccm to about 200 sccm. The Ti targets 22 are applied a power between about 3 kW to about 5 kW. A bias voltage of about −300 V to about −350 V may be applied to the stainless steel substrate 11. Depositing the primer layer 13 may last for about 8 min to about 15 min.

The transition layer 15 is deposited directly on the primer layer 13. The electric current of the RF electrode is set about 5 A to about 8 A. Argon gas is fed into the chamber 20 at a flux rate about 100 sccm to about 150 sccm. The temperature of the inside of the chamber 20 is set to about 150° C. to about 180° C. A power between about 5 kW to about 7 kW is applied to the Ti targets 22. A power between about 8 kW to about 12 kW is applied to the Cr targets 23. A bias voltage of about −350 V to about −400 V may be applied to the stainless steel substrate 11. Depositing the transition layer 15 may last for about 15 min to about 25 min.

During deposition the transition layer 15, some of the Ti ions sputtered from the Ti targets 22 and Cr ions sputtered from the Cr targets 23 are ionized to plasma by the RF electrode, thus enhancing the density of the transition layer 15 and the bond between the transition layer 15 and primer layer 15.

The hard layer 17 is deposited directly on the transition layer 15. The electric current of the RF electrode is set about 5 A to about 8 A. The temperature of the inside of the chamber 20 is set to about 150° C. to about 180° C. A power between about 4 kW to about 6 kW is applied to the Ti targets 22. A power between about 10 kW to about 15 kW is applied to the Cr targets 23. Argon gas is fed into the chamber 20 at a flux rate of about 150 sccm to about 200 sccm. Nitrogen gas is fed into the chamber 20 at a flux rate of about 300 sccm to about 500 sccm. A bias voltage of about −1300 V to about −1500 V may be applied to the stainless steel substrate 11. Depositing the hard layer 17 may last for about 25 min to about 50 min.

During deposition the hard layer 17, some of the Ti ions sputtered from the Ti targets 22 and Cr ions sputtered from the Cr targets 23 are ionized to plasma by the RF electrode, thus enhancing bonding force between Ti ion, Cr ion and N ion in the hard layer 17, the uniformity and density of the hard layer 15, thereby increasing the hardness of the hard layer 17.

The stainless steel substrate 11 coated with the hard layer 17 is cooled by feeding liquid nitrogen into the chamber 20. First, the inner temperature of coating chamber 20 is reduced to about 100° C. at a cooling rate of 3° C./min to about 5° C./min, the inner pressure of coating chamber 20 is maintained at about 2 Pa to about 5 Pa. Then, the inner temperature of coating chamber 20 is reduced from about 100° C. to about 70° C. at a cooling rate of 5° C./min to about 6° C./min, the inner pressure of coating chamber 20 is maintained at about 1 Pa to about 2 Pa.

The liquid nitrogen cooling treatment reduces the stress between layers and the stainless steel substrate 11, thus enhancing the bond between layers and stainless steel substrate 11 and the abrasion of the coated article 10.

The coated article 10 has a surface micro-hardness of about 800 HV_{0.025}-1000 HV_{0.025}. The layers formed directly on the stainless steel substrate 11 have a uniform thickness and high density.

### EXAMPLES

Experimental examples of the present disclosure are described as follows.

### Example 1

A stainless steel substrate 11 is provided.

Forming the ion implantation layer 111: the chamber 20 was evacuated to about 2×10⁻¹ Pa; the temperature in the chamber 20 was set to about 220 V; the electric current of the RF electrode was set about 6 A; a bias voltage of −1400 V was applied to the stainless steel substrate 11; the flow rate of argon gas was about 150 sccm; the flow rate of nitrogen gas was about 400 sccm; forming the ion implantation layer 111 lasted about 30 min. The thickness of the ion implantation layer 111 was about 0.15 μm.

Depositing the primer layer 13 on the ion implantation layer 111: the electric current of the RF electrode was set about 5 A to about 8 A; the flow rate of argon gas was about 150 sccm; the temperature in the chamber 20 was set to about 170 V; a power between about 4 kW was applied to the Ti targets 22; a bias voltage of −300 V was applied to the stainless steel substrate 11; depositing the primer layer 13 lasted for about 10 min. The thickness of the primer layer 13 was about 0.4 μm.

Depositing the transition layer 15 on the primer layer 13: the electric current of the RF electrode was set about 5 A to about 8 A; the flow rate of argon gas was about 150 sccm; the temperature in the chamber 20 was set to about 170° C.; a power between about 4 kW was applied to the Ti targets 22; a power between about 4 kW was applied to the Cr targets 23; a bias voltage of −400 V was applied to the stainless steel substrate 11; depositing the transition layer 15 lasted for about 20 min. The thickness of the transition layer 15 was about 0.6 μm.

Depositing the hard layer 17 on the transition layer 15: the electric current of the RF electrode was set about 5 A to about 8 A; the flow rate of argon gas was about 150 sccm; the temperature in the chamber 20 was set to about 170° C.; a power about 5 kW was applied to the Ti targets 22; a power about 12 kW was applied to the Cr targets 23; a bias voltage of −1400 V was applied to the stainless steel substrate 11; depositing the hard layer 17 lasted for about 40 min. The thickness of the hard layer 17 was about 1.4 μm.

Cooling the stainless steel substrate 11 using liquid nitrogen: First, the inner temperature of coating chamber 20 was reduced to about 100° C. at a cooling rate of 3° C./min, the inner pressure of coating chamber 20 was maintained at about 4 Pa. Then, the inner temperature of coating chamber 20 was reduced from about 100° C. to about 70° C. at a cooling rate of 5° C./min, the inner pressure of coating chamber 20 was maintained at about 2 Pa.

The coated article 10 manufacturing by Example 1 has a surface micro-hardness of about 815 HV_{0.025}.

### Example 2

A stainless steel substrate 11 is provided.

Forming the ion implantation layer 111: the chamber 20 was evacuated to about 5×10⁻¹ Pa; the temperature in the chamber 20 was set to about 220° C.; the electric current of the RF electrode was set at about 8 A; a bias voltage of −1400 V was applied to the stainless steel substrate 11; the flow rate of argon gas was about 200 sccm; the flow rate of nitrogen gas was about 600 sccm; forming the ion implantation layer 111 lasted about 30 min. The thickness of the ion implantation layer 111 was about 0.15 μm.

Depositing the primer layer 13 on the ion implantation layer 111: the electric current of the RF electrode was set about 8 A; the flow rate of argon gas was about 150 sccm; the temperature in the chamber 20 was set to about 200° C.; the Ti targets 22 were applied a power between about 5 kW; a bias voltage of −350 V was applied to the stainless steel substrate 11; depositing the primer layer 13 lasted for about 10 min. The thickness of the primer layer 13 was about 0.5 μm.

Depositing the transition layer 15 on the primer layer 13: the electric current of the RF electrode was set about 8 A; the flow rate of argon gas was about 150 sccm; the temperature in the chamber 20 was set to about 200° C.; a power about 7 kW was applied the Ti targets 22; a power about 12 kW was applied to the Cr targets 23; a bias voltage of −400 V was applied to the stainless steel substrate 11; depositing the transition layer 15 lasted for about 25 min The thickness of the transition layer 15 was about 0.7 μm.

Depositing the hard layer 17 on the transition layer 15: the electric current of the RF electrode was set about 8 A; the flow rate of argon gas was about 200 sccm; the temperature in the chamber 20 was set to about 200° C.; a power about 6 kW was applied the Ti targets 22; a power about 15 kW was applied the Cr targets 23 were applied; a bias voltage of −1500 V was applied to the stainless steel substrate 11; depositing the hard layer 17 lasted for about 40 min. The thickness of the hard layer 17 was about 1.5 μm.

Cooling the stainless steel substrate 11 using liquid nitrogen: First, the inner temperature of coating chamber 20 was reduced to about 100° C. at a cooling rate of 5° C./min, the inner pressure of coating chamber 20 was maintained at about 4 Pa. Then, the inner temperature of coating chamber 20 was reduced from about 100° C. to about 70° C. at a cooling rate of 6° C./min, the inner pressure of coating chamber 20 was maintained at about 1 Pa.

The coated article 10 manufacturing by Example 1 has a surface micro-hardness of about 1000 HV_{0.025}.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A coated article, comprising:
a stainless steel substrate;
a primer layer formed directly on the stainless steel substrate, the primer layer being a Ti layer;
a transition layer formed directly on the prime bonding layer, the transition layer being TiₐCr_{b} layer, wherein 1≦a≦2 and 2≦b≦3; and
a hard layer formed directly on the transition layer, the hard layer being a TiₓCr_{y}N_{z} layer, wherein 2≦x≦4, 3≦y≦8 and 10≦z≦16.

2. The coated article as claimed in claim 1, wherein the stainless steel substrate has a ion implantation layer, the primer layer is formed directly on the ion implantation layer, the ion implantation layer substantially comprises Fe element and N element.

3. The coated article as claimed in claim 2, wherein in the ion implantation layer, the atomic ratio of the Fe to N is about 1:4 to about 1:7.

4. The coated article as claimed in claim 2, wherein the thickness of the ion implantation layer is about 0.1 μm to about 0.2 μm.

5. The coated article as claimed in claim 1, wherein the primer layer has a thickness of about 0.3 μm to about 0.5 μm.

6. The coated article as claimed in claim 1, wherein the transition layer has a thickness of about 0.5 μm to about 0.8 μm.

7. The coated article as claimed in claim 1, wherein the coated article has a surface micro-hardness of about 800 HV_{0.025}-1000 HV_{0.025}.

8. A method for manufacturing a coated article, comprising steps of:
providing a stainless steel substrate;
providing a vacuum sputtering device, the vacuum sputtering device comprising a chamber, two Ti targets, two Cr targets, a radio frequency electrode mounted in the chamber, the frequency electrode being used to ionize metal ions and gases to plasma;
forming a primer layer on the stainless steel substrate by vacuum sputtering using the vacuum sputtering device, the primer layer being a Ti layer;
forming a transition layer on the primer layer by vacuum sputtering a transition layer, the transition layer being TiₐCr_{b} layer, wherein 1≦a≦2 and 2≦b≦3; and
forming a hard layer on the transition layer by vacuum sputtering, the hard layer being a TiₓCr_{y}N_{z} layer, wherein 2≦x≦4, 3≦y≦8 and 10≦z≦16.

9. The method as claimed in claim 8, further comprising a step of forming a ion implantation layer on the stainless steel substrate before forming the primer layer, during forming the ion implantation layer, argon gas and nitrogen gas are fed into the chamber.

10. The method as claimed in claim 9, wherein during forming the ion implantation layer, the electric current of the radio frequency electrode is set about 5 A to about 8 A, a bias voltage of about −1300 V to about −1500 V is applied to the stainless steel substrate, the flow rate of argon gas is about 100 sccm to about 200 sccm, he flow rate of nitrogen gas is about 200 sccm to about 600 sccm, forming the ion implantation process take about 20 min to about 35 min.

11. The method as claimed in claim 8, wherein during forming the primer layer, the temperature of the inside of the chamber is set to about 150° C. to about 200 V, the electric current of the radio frequency electrode is set about 5 A to about 8 A, the flow rate of argon gas is about 100 sccm to about 200 sccm, the Ti targets are applied a power between about 3 kW to about 5 kW, a bias voltage of about −300 V to about −350 V is applied to the stainless steel substrate, depositing the primer layer lasts for about 8 min to about 15 min.

12. The method as claimed in claim 8, wherein during forming the transition layer, the electric current of the radio frequency electrode is set about 5 A to about 8 A, the flow rate of argon gas is about 100 sccm to about 150 sccm, the temperature of the inside of the chamber is set to about 150° C. to about 180° C., the Ti targets are applied a power between about 5 kW to about 7 kW, the Cr targets are applied a power between about 8 kW to about 12 kW, a bias voltage of about −350 V to about −400 V is applied to the stainless steel substrate, depositing the transition layer lasts for about 15 min to about 25 min.

13. The method as claimed in claim 8, wherein during forming the hard layer, the electric current of the radio frequency electrode is set about 5 A to about 8 A, the temperature of the inside of the chamber is set to about 150° C. to about 180° C., the Ti targets are applied a power between about 4 kW to about 6 kW, the Cr targets re applied a power between about 10 kW to about 15 kW, the flow rate of argon gas is about 150 sccm to about 200 sccm, the flow rate of argon gas nitrogen gas is about 300 sccm to about 500 sccm, a bias voltage of about −1300 V to about −1500 V is applied to the stainless steel substrate, depositing the hard layer lasts for about 25 min to about 50 min.
